(19) United States
(12) Patent Application Publication
(10) Pub. No.: US 2012/0273652 A1
(43) Pub. Date: Nov. 1, 2012

(54) SYSTEMS AND METHODS FOR IMAGE SENSING

(75) Inventor: VICTOR LENCHENKOV, Sunnyvale, CA (US)

(73) Assignee: APTINA IMAGING CORPORATION, Georgetown Grand Cayman (KY)

(21) Appl. No.: 13/176,945

(22) Filed: Jul. 6, 2011

Related U.S. Application Data
(60) Provisional application No. 61/480,041, filed on Apr. 28, 2011.

(51) Int. Cl. H01L 27/146; H01L 31/0232

(52) U.S. Cl. 250/208.1; 257/432; 257/E31.127

(57) ABSTRACT

Systems and methods for image sensing are disclosed. An image sensor includes a pixel having an active region and a plurality of reflective interfaces. The active region is configured to convert light absorbed by the pixel into an electrical signal. The plurality of reflective interfaces cause the light absorbed by the pixel to resonate within the active region. A method for converting absorbed light into an electrical signal with an image sensor includes absorbing light with the pixel of the image sensor, and reflecting the absorbed light with a plurality of reflective interfaces embedded in the pixel to generate a resonance within the active region.

### CROSS REFERENCE TO RELATED APPLICATIONS

This application claims priority from U.S. Provisional Patent Application No. 61/480,041 filed Apr. 28, 2011, the contents of which are incorporated herein by reference.

### FIELD OF THE INVENTION

The present invention relates generally to image sensors, and more particularly, to improvements in photodetectors for image sensors.

### BACKGROUND OF THE INVENTION

Image sensors convert optical light to an electrical signal. Conventional image sensors are used predominantly in digital cameras, and may fall into one of two categories: charge-coupled device (CCD) image sensors and complementary metal-oxide-semiconductor (CMOS) image sensors.

Image sensors are formed from an array of photodetectors, each of which is converts received light into an electrical signal. The effectiveness of a photodetector at converting received light into an electrical signal is the Quantum Efficiency (QE) of the photodetector. There is an omnipresent desire in the field of image sensing for photodetectors having improved QEs.

### BRIEF DESCRIPTION OF THE DRAWINGS

The invention is best understood from the following detailed description when read in connection with the accompanying drawings, with like elements having the same reference numerals. When a plurality of similar elements are present, a single reference numeral may be assigned to the plurality of similar elements with a small letter designation referring to specific elements. When referring to the elements collectively or to a non-specific one or more of the elements, the small letter designation may be dropped. According to common practice, the various features of the drawings are not drawn to scale unless otherwise indicated. To the contrary, the dimensions of the various features may be expanded or reduced for clarity. Included in the drawings are the following figures:

FIG. 1 is a diagram illustrating an example image sensor in accordance with aspects of the present invention;

FIG. 2 is a diagram illustrating an example photodetector in accordance with aspects of the present invention;

FIG. 3 is a diagram illustrating one example reflective interface for the photodetector of FIG. 2;

FIG. 4 is a diagram illustrating another example reflective interface for the photodetector of FIG. 2;

FIG. 5 is a diagram illustrating yet another example reflective interface for the photodetector of FIG. 2;

FIG. 6 is a diagram illustrating another example reflective interface for the photodetector of FIG. 2;

FIG. 7 is a graph illustrating the quantum efficiency of an example photodetector in accordance with aspects of the present invention;

FIG. 8 is a diagram illustrating another example photodetector in accordance with aspects of the present invention; and

FIG. 9 is a flowchart illustrating an example method for converting absorbed light into an electrical signal in accordance with aspects of the present invention.

### DETAILED DESCRIPTION OF THE INVENTION

The example embodiments disclosed herein are particularly suitable for use in conjunction with complementary metal-oxide-semiconductor (CMOS) image sensors. Nonetheless, while the example embodiments of the present invention are described herein in the context of CMOS image sensors, it will be understood by one of ordinary skill in the art that the invention is not so limited.

The image sensors described herein are usable for a variety of electronic devices including, for example, digital cameras. The disclosed image sensors may achieve Quantum Efficiencies (QEs) far in excess of conventional image sensors.

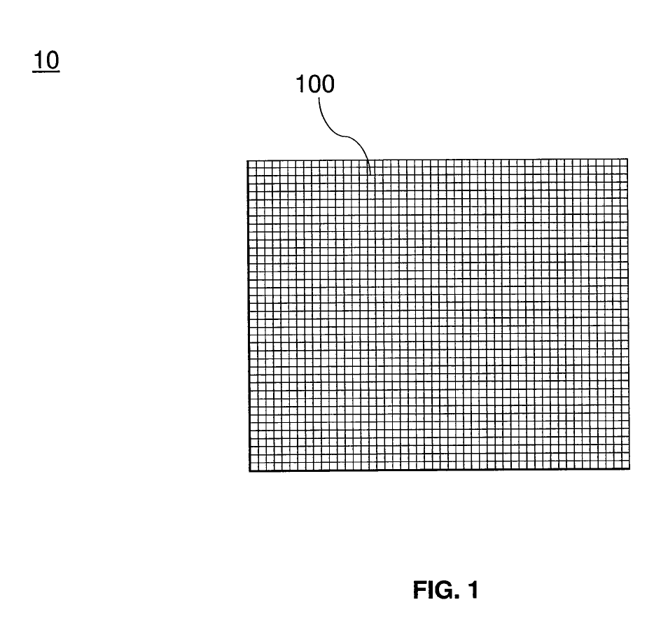

Referring now to the drawings, FIG. 1 illustrates an example image sensor array 10 in accordance with aspects of the present invention. Image sensor array 10 may be part of an electronic device such as, for example, a digital camera. As a general overview, image sensor array 10 includes an array of photodetectors 100. Additional details of image sensor array 10 are described below.

Photodetectors 100 of image sensor 10 are arranged and electrically connected in a conventional manner. Suitable layouts for the array of photodetectors 100 will be known to one of ordinary skill in the art from the description herein. For example, image sensor 10 may include an array of photodetectors that are arranged and connected similarly to those in U.S. Pat. No. 6,140,630 to Rhodes, the contents of which are incorporated herein by reference for their teaching on the structure and operation of image sensor arrays.

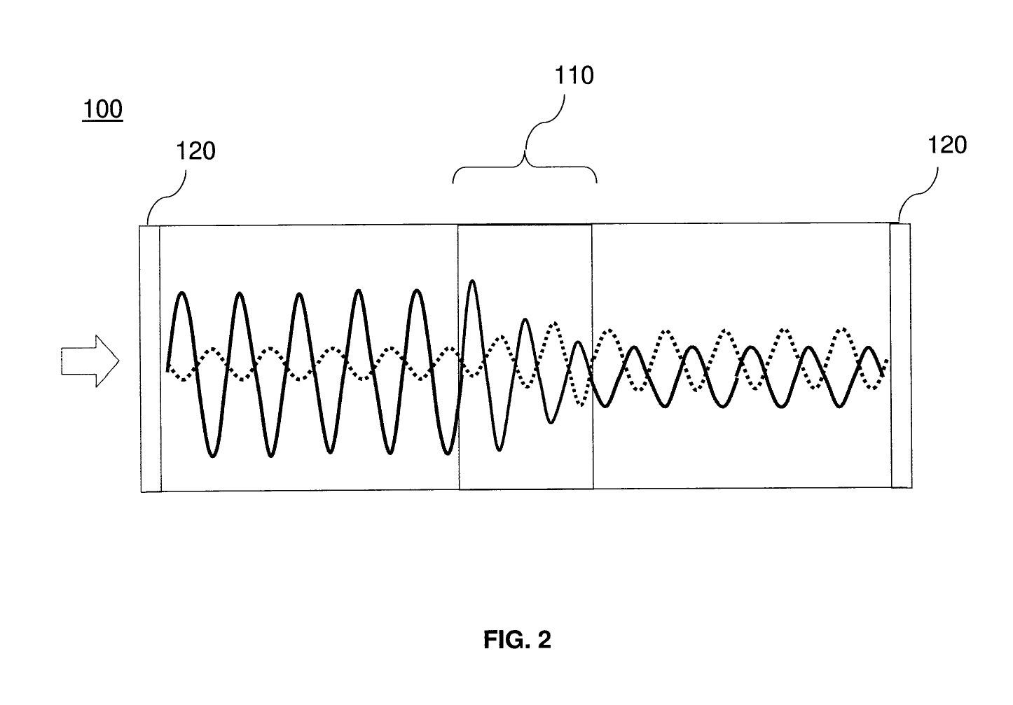

FIGS. 2-7 illustrate a portion of an example photodetector 100 in accordance with aspects of the present invention. Photodetector 100 may be, for example, the photodiode of an active pixel sensor (APS) CMOS image sensor array. As a general overview, photodetector 100 includes an active region 110 and a plurality of reflective interfaces 120. Additional details of photodetector 100 are described below.

As shown in FIG. 2, active region 110 is configured to convert light absorbed by photodetector 100 into an electrical signal. Briefly, a semiconductor p-n junction diode is often used for the detection of light signals. The p-n junction is typically reverse biased, creating a depletion region in a volume surrounding the p-n junction. As such, light illuminating the p-n junction cause electrons in the valance band of the semiconductor material to transition into the conduction band, generating hole-electron pairs in the depletion region which are swept out of the depletion region in opposite directions. A change in junction potential due to collapse of the depletion region is detected as the signal indicative of the incident light intensity. Although the invention is described in terms of a photodiode, it is contemplated that it may be provided in CCD devices where the depletion region is beneath the photogate.

The active region 110 may include a depletion region (comprising a semiconductor material) positioned between an anode and a cathode of photodetector 100. In the active region 110, photons of the light may be absorbed by the semiconductor material, thereby generating a free negative charge carrier (i.e. an electron) and a free positive charge character (i.e. a hole). The free negative and positive charge carriers are biased to move toward the cathode and anode, respectively, of the active region. This generates an accumulation of electrical charge which causes a change in the potential across the reverse-biased photodiode. This electrical charge is read from the photodiode as an electrical signal representative of the light absorbed by the active region 110 of the photodetector 100.

A p-n junction diode intended for use as a photodetector is often referred to as a photodiode. Various physical mechanisms act to limit the ability of the photodiode and photodiode arrays to detect and specially resolve low levels of light. Important among these mechanisms are noise, surface reflectivity, leakage currents, and cross-talk. Noise may be due to random fluctuations in light signal intensity, thermal mechanisms, and other causes. Other characteristics of the photodiode, such as depth of the junction below the semiconductor surface and width of depletion region, also influence the sensitivity of the photodiode to the incident light.

In an example embodiment, a plurality of reflective interfaces 120 may be formed to reflect the light that propagates within photodetector 100. Reflective interfaces 120 are positioned so that they reflect the light toward active region 110 (left to right for the solid line in FIG. 2, right to left for the dotted line in FIG. 2). Thereby, the plurality of reflective interfaces 120 cause the light traversing photodetector 100 to resonate within active region 110. As used herein, the terms “resonate” or “resonance” refer to standing wave resonance of an optical light wave within the active region 110 of photodetector 100. The light resonating within the active region 110 may desirably enable active region 110 to absorb more of the light traversing photodetector 100. This in turn may increase the generation of signal electrons within active region 110, thereby increasing the QE of photodetector 100.

Reflective interfaces 120 may be positioned in front of and/or behind active region 110 (relative to the source of the light absorbed by photodetector 100). Where reflective interfaces 120 are positioned in front of active region 110 relative to the light source (i.e. the block arrow in FIG. 2), it is desirable that reflective interfaces 120 be at least partially transmissive. Accordingly, light traversing photodetector 100 may be allowed to enter active region 110 before it is reflected by reflective interfaces 120 (causing the above-described resonance). Partial reflectors and reflective interfaces forming the resonator may be made based on: 1) Fresnel index contrast reflections between different semiconductor materials; 2) Additional semiconductor material layer(s); 3) plasmon-based 3D structures; 4) photonic band gap filter structures; 5) geometrically set up resonators; or 6) a combination of any of 1-5 with absorption filters. Examples of these reflective interfaces are set forth below.

### EXAMPLES OF THE INVENTION

It will be understood that the example reflective interfaces 120 described herein are for the purposes of illustration, and are not intended to limit the structure of the reflective interfaces 120 of the present invention. It will be understood by one of ordinary skill in the art that the reflective interfaces 120 may be any suitable surface that reflects the light (or a portion thereof) absorbed by photodetector 100 in order to cause resonance in active region 110. The orientation of reflective interfaces 120 in the example embodiments set forth below approximate the resonance effect of a Fabry-Perot interferometer within the active region 110 of photodetector 100, as would be understood by one of ordinary skill in the art from the description herein.

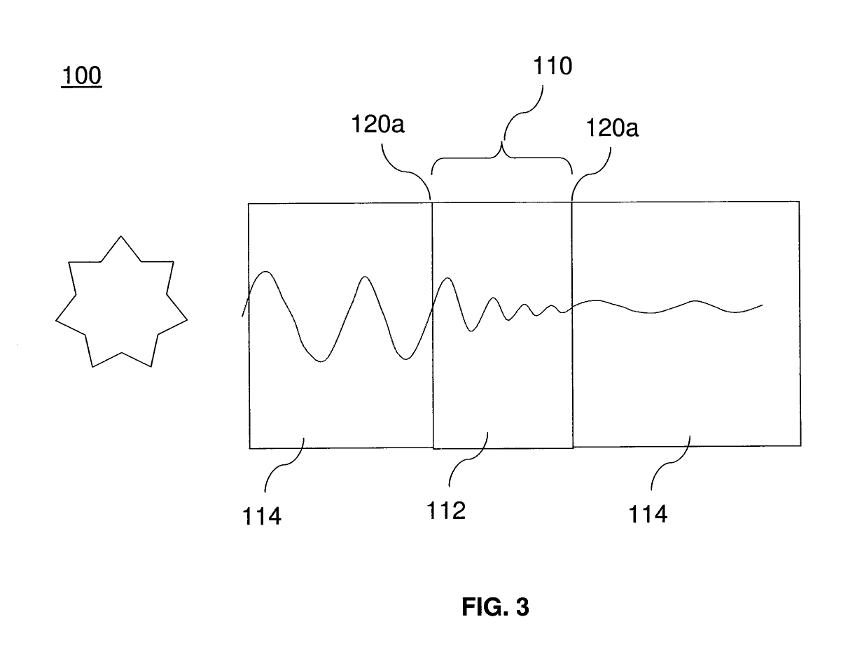

In one example embodiment, the plurality of reflective interfaces 120 comprises boundaries between two materials having different refractive indexes, as shown in FIG. 3. For example, active region 110 may include a first material 112 (as set forth above) having a first refractive index. First material 112 may be silicon, for example. Photodetector 100 may include a second material 114 on either side of active region 110 that has a different refractive index than the material of active region 110. Second material 114 may be SiO₂, SiN, SiC, SiN, HfO₂, and/or W, for example. Suitable processes for the fabrication of photodetectors 100 having different layers of material 112, 114 are described, for example, in U.S. Patent Application Publication No. 2010/01640428 to Manabe, the contents of which are incorporated herein by reference for their teaching on the fabrication of image sensors and pixels. In this embodiment, boundaries 120a between the different materials reflect the light back and forth within active region 110, thereby causing resonance of the absorbed light.

In another example embodiment, the plurality of reflective interfaces 120 comprise layers of reflective material positioned on opposite sides of active region 110. The shape, size, and composition of the reflective material layers may be chosen based on the light to be resonated within active region 110, as shown below.

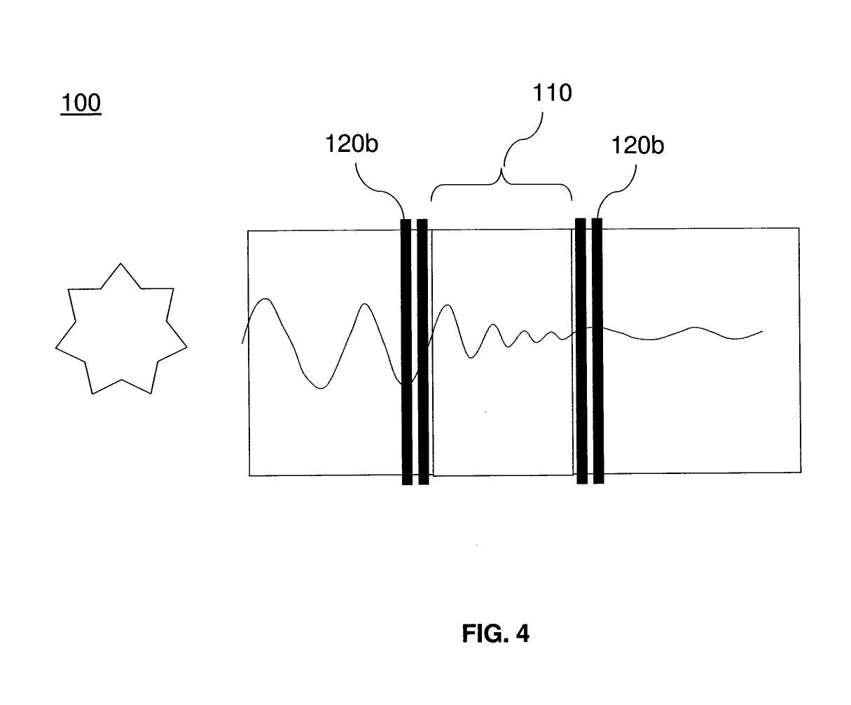

For example, photodetector 100 may include reflective material layers formed as interference filters 120b on either side of active region 110, as shown in FIG. 4. Interference filters 120b may be formed using similar processes as those described above with respect to the embodiment of FIG. 3. For example, multiple layers of material having different refractive indexes may be deposited to form diffraction gratings that are tuned to reflect light in a particular wavelength band. Interference filters 120b may be designed to transmit portions of the light that are not of interest, while reflecting (and confining) certain wavelength ranges that are desired to be absorbed within active region 110. In this way, interference filters 120b may be used to generate photodetectors 100 that are sensitive to predetermined wavelength ranges of light.

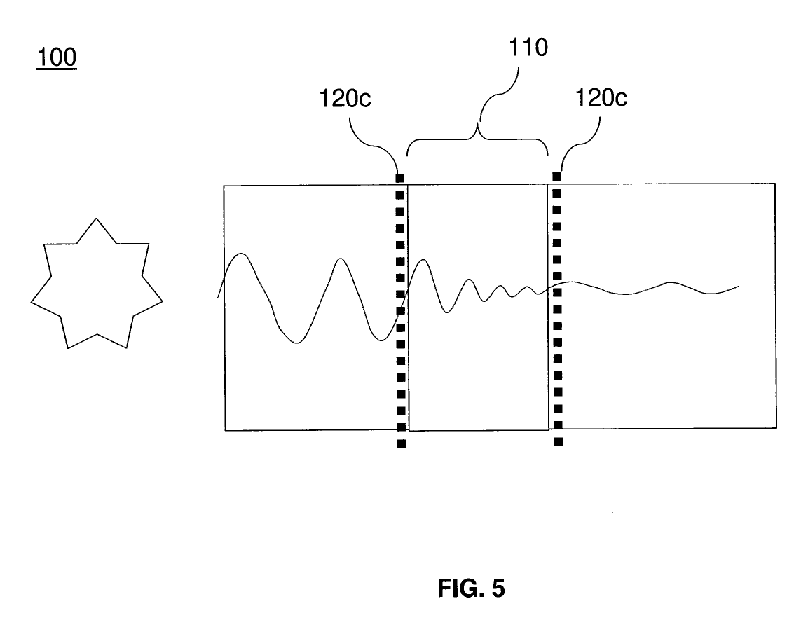

For another example, the layers of reflective material may be formed as three-dimensional (3D) structures 120c embedded in photodetector 100, as shown in FIG. 5. The 3D structures 120c may be shaped as dots, lines, or other suitable shapes. 3D structures 120c may be formed, for example, using techniques similar to those used to form shallow trench isolation structures. One suitable shallow trench isolation process for forming 3D structures 120c is set forth in U.S. Pat. No. 6,897,120 to Trapp, the contents of which are incorporated herein by reference. One suitable material for 3D structures 120c includes plasmon-based conductive material. Another suitable material for 3D structures 120c includes a separate semiconductor material such as, for example, Al, W, and/or Cu.

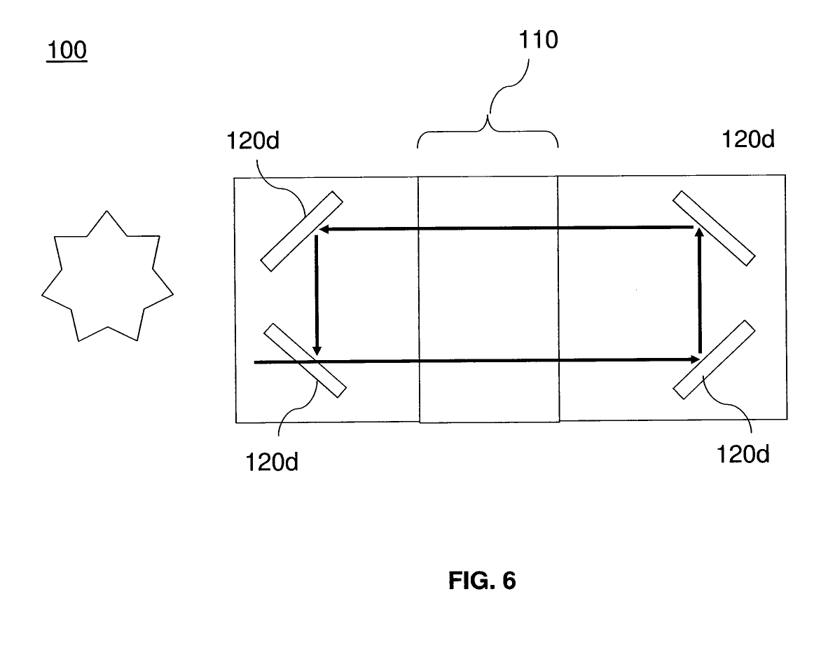

In yet another example embodiment, the plurality of reflective interfaces 120 comprise surfaces oriented to reflect the light absorbed by photodetector 100 in different directions, as shown in FIG. 6. For example, light absorbed by photodetector 100 may propagate in a first direction through photodetector 100. Photodetector 100 may include a reflective surface 120d oriented to reflect the light in a second direction not parallel to the first direction (e.g., orthogonally in FIG. 6). This may desirably allow the light absorbed by photodetector 100 to resonate over a larger portion of the active region 110, and further improve the QE of photodetector 100. Reflective surface 120d may be formed, for example, using any of the processes described above with respect to the other embodiments of photodetector 100. Suitable materials for use in forming reflective surface 120d include aluminum deposited as one of the metal layers. Additional materials include, for example, Cu, W, polycrystalline Si, amorphous Si, Ag, and/or Au. Additionally, reflective surface 120d may be formed by air (either a pocket of air within photodetector 100 or at an outer edge of photodetector 100).

It will be understood by one of ordinary skill in the art that the reflective interfaces 120 described above is not limited to reflecting all of the light absorbed by photodetector 100. As described with respect to interference filters 120b, one or all of the reflective interfaces may be designed to reflect only a predetermined wavelength range of the light absorbed by the photodetector 100. Accordingly, photodetectors 100 may be configured to resonate predetermined wavelength ranges of light using reflective interfaces 120. In one embodiment, an image sensor 10 may be created have specialized groups or arrays of photodetectors 100 for each wavelength range (e.g. color) desired to be imaged.

Additionally, the wavelength range for a respective photodetector 100 may be predetermined based on the shapes, sizes, and materials of active region 110 and reflective interfaces 120. For example, the depth of active region 110 (in the direction of propagation of the absorbed light) may be lengthened or shortened based on the wavelength of the light desired to be imaged. Further, the positioning and distance between reflective interfaces 120 may be altered based on the wavelength of the light desired to be imaged. Where the reflective interfaces comprise boundaries between different materials, the indices of refraction of those materials may be chosen based on the wavelength of the light desired to be imaged. Finally, where reflective interfaces 120 comprise layers of reflective material, the reflective material may be chosen based on the wavelength of the light desired to be imaged. The selection of shapes, sizes, and materials for active region 110 and reflective interfaces 120 to optimize the resonance of a predetermined wavelength range of light will be understood by one of ordinary skill in the art from the description herein.

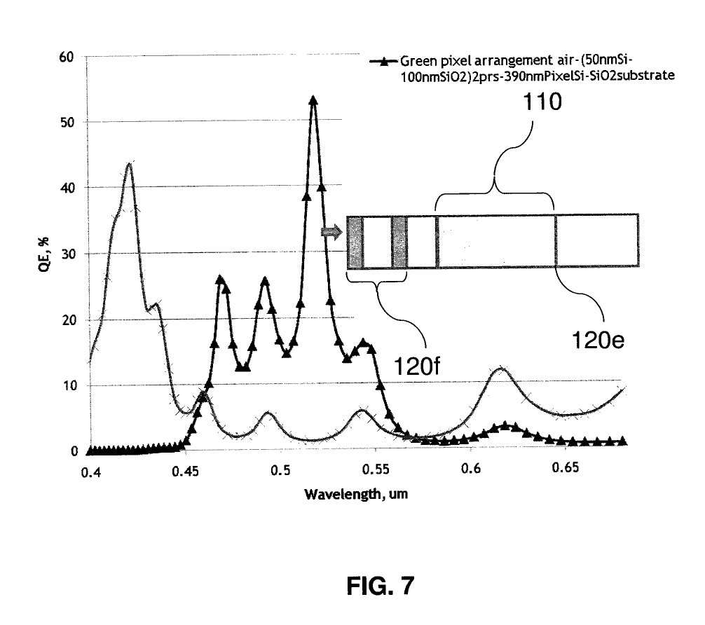

The tuning of the color or wavelength range of photodetector 100 is now described with reference to FIG. 7. It may be desired for a photodetector to absorb and generate an electrical signal for optical wavelengths falling within the 450-550 nm range (e.g. a green pixel). This photodetector may be designed to have an active region 110 with a depth at the low end of the predetermined wavelength range (e.g., approximately 390 nm in FIG. 7). Reflective interfaces may be positioned on either side of the active region with a distance apart at the high end of the predetermined range. As shown in FIG. 7, one reflective interface 120e comprises a boundary between the active region material (Si) and a second semiconductor material (SiO₂). The other reflective interface 120f comprises an interference filter formed from two 50 nm layers of Si spaced apart by a 100 nm layer of SiO₂. Reflective interface 120f is centered approximately 590 nm from reflective interface 120e and forms a green resonant pixel. With the above structure, when white optical light is received by the photodetector, the wavelengths falling within the predetermined optical wavelength will resonate within the active region, due to the correspondence between the predetermined wavelengths and either the depth of the active region and/or the distance between the reflective interfaces. This greatly increases the quantum efficiency of the photodetector in the desired wavelength range, as shown by the graph in FIG. 7.

In an alternative to the above example, the size of the active region and the spacing of the reflective surfaces may be tuned to 500 nm, the center of the desired range. Additionally, by adjusting the materials and spacing of reflective interfaces 120, this example could be tuned to absorb optical wavelengths falling within the 400-450 nm range (e.g., a blue pixel). For example, a blue resonator may be formed by changing the material of reflective interface 120f from Si to SiC.

While different embodiments of reflective interfaces 120 are illustrated separately in FIGS. 2-6, it will be understood that photodetector 100 may incorporate any combination of the above interfaces, or two or more different types of reflective interfaces 120, in order to maximize resonance of the absorbed light within active region 110. Different types of reflective interfaces 120 may be positioned differently within photodetector 100 based on the wavelength of light desired to be absorbed within active region 110, as set forth above.

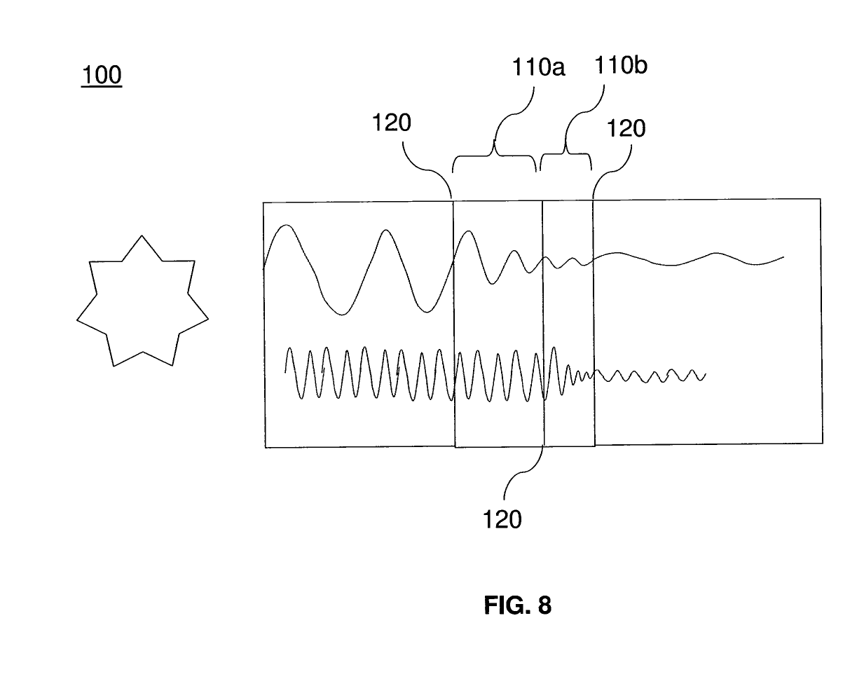

Additionally, while photodetector 100 is illustrated as having a single active region 110 in FIGS. 2-6, it will be understood by one of ordinary skill in the art that photodetector 100 is not so limited. As shown in FIG. 8, photodetector 100 may include a plurality of active regions 110a and 110b. In this embodiment, the plurality of reflective interfaces 120 may be configured to cause light absorbed by photodetector 100 to resonate at a first frequency within one active region 110a and at a second frequency within another active region 110b. Accordingly, photodetector 100 may be designed to optimize detection of light at multiple distinct wavelength ranges by using multiple overlapping or distinct active regions 110.

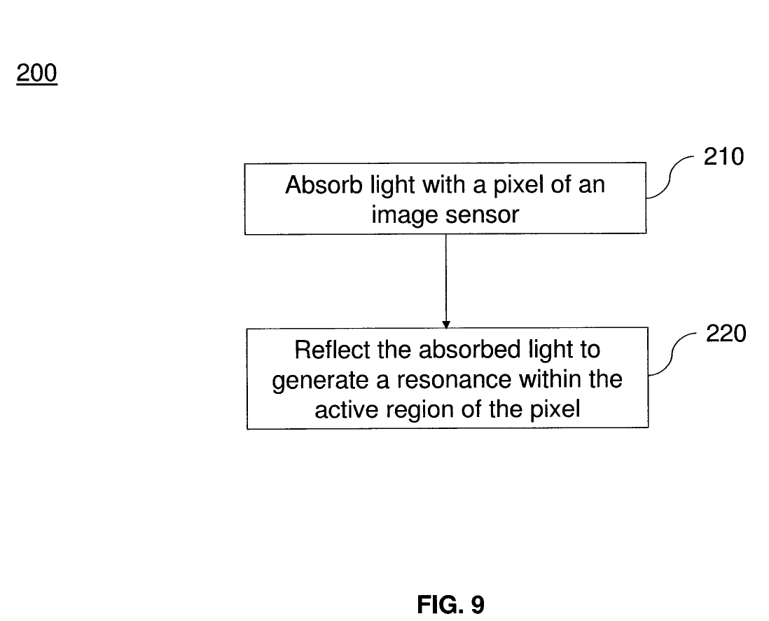

FIG. 9 shows an example method 200 for converting absorbed light into an electrical signal with an image sensor in accordance with aspects of the present invention. Method 200 may desirably be implemented, for example, with a CMOS image sensor of a digital camera. As a general overview, method 200 includes absorbing light with a photodetector and reflecting the absorbed light to generate a resonance. Additional details of method 200 are described herein with respect to the components of image sensor 10 and photodetector 100.

In step 210, light is absorbed with a photodetector. In an example embodiment, photodetector 100 of image sensor 10 absorbs light to be converted into an electrical signal for imaging. Photodetector 100 has an active region 110 configured to convert the absorbed light into the electrical signal, as set forth above.

In step 220, the absorbed light is reflected within the photodetector. In an example embodiment, photodetector 100 includes a plurality of reflective interfaces 120 embedded within photodetector 100. The reflective interfaces 120 reflect the absorbed light in such a way as to generate a resonance within the active region 110 of photodetector 100.

As set forth above with respect to FIG. 3, the absorbed light may be reflected at a boundary between two different types of material. Alternatively, as described above with respect to FIGS. 4 and 5, the absorbed light may be reflected using layers of reflective material positioned on opposite sides of the active region 110. In additional, as set forth above with respect to FIG. 6, the absorbed light may be reflected in a direction not parallel to the direction of propagation of the light within the photodetector.

It will be understood that method 200 is not limited to the above steps, but may include alternative steps and additional steps, as would be understood by one of ordinary skill in the art from the description herein.

For one example, it may be desirable to reflect only a predetermined wavelength range of the light absorbed by photodetector 100, as set forth above. Accordingly, step 220 may include reflecting a predetermined wavelength range of the absorbed light to generate a resonance of only the predetermined wavelength range within active region 110.

Aspects of the present invention relate to systems and methods for image sensing.

According to one aspect of the present invention, an example pixel for an image sensor is disclosed. The pixel comprises an active region and a plurality of reflective interfaces. The active region is configured to convert light absorbed by the pixel into an electrical signal. The plurality of reflective interfaces cause the light absorbed by the pixel to resonate within the active region.

According to another aspect of the present invention, an example method for converting absorbed light into an electrical signal with an image sensor is disclosed. The method comprises the steps of absorbing light with a pixel of the image sensor, the pixel having an active region configured to convert the absorbed light into the electrical signal, and reflecting the absorbed light with a plurality of reflective interfaces embedded in the pixel to generate a resonance within the active region.

Accordingly to still another aspect of the present invention, an example image sensor is disclosed. The image sensor includes a plurality of pixels, with at least one pixel having an active region and a plurality of reflective interfaces. The active region is configured to convert light absorbed by the pixel into an electrical signal. The plurality of reflective interfaces cause the light absorbed by the pixel to resonate within the active region.

The above aspects of the present invention may achieve advantages not present in prior art image sensors, as set forth below.

By generating standing wave resonance within the active region of a photodetector, the photodetectors described herein may be able to convert substantially all of the energy of the absorbed light into an electrical signal. This results in a substantially increased QE with respect to prior art photodetectors. Additionally, the disclosed photodetectors and image sensors may be smaller than prior art devices, which rely on increasing the depth of the photodetector active region in order to increase generation of signal electrons. Further, the disclosed photodetectors may allow for color or wavelength tunability of specific photodetectors within the photodetector itself, thereby eliminating the need for external filters or signal processing.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A pixel for an image sensor comprising:
an active region configured to convert light absorbed by the pixel into an electrical signal; and
a plurality of reflective interfaces, the reflective interfaces causing the light absorbed by the pixel to resonate within the active region.

2. The pixel of claim 1, wherein
the active region comprises a first material,
the pixel further comprises a second material having a refractive index different from the first material positioned on opposite sides of the active region, and
the plurality of reflective interfaces comprise the boundaries between the first material and the second material.

3. The pixel of claim 1, wherein the plurality of reflective interfaces comprises layers of reflective material positioned on opposite sides of the active region.

4. The pixel of claim 3, wherein the layers of reflective material comprise interference filters.

5. The pixel of claim 3, wherein the layers of reflective material comprise three-dimensional structures embedded in the pixel.

6. The pixel of claim 5, wherein the three-dimensional structures comprise plasmon-based conductive material.

7. The pixel of claim 5, wherein the three-dimensional structures comprise semiconductor material.

8. The pixel of claim 1, wherein
the light absorbed by the pixel propagates in a first direction, and
the plurality of reflective interfaces comprises at least one reflective interface configured to reflect the light in a second direction not parallel to the first direction.

9. The pixel of claim 1, wherein the plurality of reflective interfaces are configured to cause a predetermined wavelength range of the light absorbed by the pixel to resonate within the active region.

10. The pixel of claim 1, wherein
the pixel comprises a plurality of active regions, and
the plurality of reflective interfaces cause the light absorbed by the pixel to resonate at a first frequency within a first of the plurality of active regions and at a second frequency within a second of the plurality of active regions.

11. A method for converting absorbed light into an electrical signal with an image sensor comprising the steps of:
absorbing light with a pixel of the image sensor, the pixel having an active region configured to convert the absorbed light into the electrical signal; and
reflecting the absorbed light with a plurality of reflective interfaces embedded in the pixel to generate a resonance within the active region.

12. The method of claim 11, wherein the reflecting step comprises:
reflecting the absorbed light at a boundary between a first material in the pixel and a second material in the pixel.

13. The method of claim 11, wherein the reflecting step comprises:
reflecting the absorbed light with a layer of reflective material positioned on opposite sides of the active region of the pixel.

14. The method of claim 11, wherein
the absorbing step comprises absorbing light propagating in a first direction with the pixel, and
the reflecting step comprises reflecting the absorbed light in a second direction not parallel to the first direction.

15. The method of claim 11, wherein the reflecting step comprises:
reflecting a predetermined wavelength range of the absorbed light to generate a resonance of the predetermined wavelength range within the active region.

16. An image sensor comprising:
a plurality of pixels, at least one of the plurality of pixels having:
an active region configured to convert light absorbed by the pixel into an electrical signal; and
a plurality of reflective interfaces, the reflective interfaces causing the light absorbed by the pixel to resonate within the active region.

17. The image sensor of claim 16, wherein
the active region of the at least one pixel comprises a first dielectric material,
the at least one pixel further comprises a second material having a refractive index different from the first material positioned on opposite sides of the active region, and
the plurality of reflective interfaces comprises the boundaries between the first material and the second material.

18. The image sensor of claim 16, wherein the plurality of reflective interfaces of the at least one pixel comprises layers of reflective material positioned on opposite sides of the active region.

19. The image sensor of claim 16, wherein
the light absorbed by the at least one pixel propagates in a first direction, and
the plurality of reflective interfaces comprises a first reflective interface configured to reflect the light in a second direction not parallel to the first direction.

20. The image sensor of claim 16, wherein the plurality of reflective interfaces of the at least one pixel are configured to cause a predetermined wavelength range of the light absorbed by the at least one pixel to resonate within the active region.
